(19) United States
(12) Patent Application Publication
(10) Pub. No.: US 2026/0353949 A1
(43) Pub. Date: Nov. 5, 2026

(54) DISPLAY PANEL AND MANUFACTURING METHOD THEREFOR, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Wei WANG, Beijing (CN); Peng XU, Beijing (CN); Liheng WEI, Beijing (CN); Maoying LIAO, Beijing (CN); Jian ZENG, Beijing (CN); Xianfu WU, Beijing (CN); Chunyan LI, Beijing (CN); Changlong YUAN, Beijing (CN); Yi ZHANG, Beijing (CN)

(21) Appl. No.: 19/476,662

(22) PCT Filed: Sep. 12, 2024
(86) PCT No.: PCT/CN2024/118538

§ 371 Date: Oct. 17, 2025

(30) Foreign Application Priority Data
Nov. 30, 2023 (CN) 202311628616.9

(51) Int. Cl. H10K 59/131; H10K 59/12; H10K 59/124

(52) U.S. Cl. CPC H10K 59/131; H10K 59/1201; H10K 59/124

(57) ABSTRACT

A display panel includes a display region and a bezel region. The bezel region includes: a substrate, a first insulating layer and a plurality of metal traces. The first insulating layer is disposed on a side of the substrate and extends from the display region to the bezel region. The metal traces are disposed on a side of the first insulating layer away from the substrate and are arranged sequentially in a direction away from the display region. The metal traces includes a first region and a second region. The first region is disposed between the display region and the second region. An orthographic projection of each of the metal traces in the first region on the first insulating layer overlaps with the first insulating layer. The first insulating layer is absent on a side of metal traces in the second region close to the substrate.

The present disclosure is a US national stage of international application No. PCT/CN2024/118538, filed on Sep. 12, 2024, which claims priority to Chinese Patent Application No. 202311628616.9, filed on Nov. 30, 2023, and entitled “DISPLAY PANEL, PREPARATION METHOD THEREOF, AND DISPLAY APPARATUS”, the disclosures of which are incorporated herein by reference in their entireties.

### TECHNICAL FIELD

The present disclosure relates to the technical field of display, and in particular, to a display panel, a preparation method thereof, and a display apparatus.

### BACKGROUND

With the development of organic light-emitting diodes (OLEDs), narrow bezels for display apparatuses have become increasingly popular. However, under a narrow bezel, there is a height variation in a region under the touch trace, for example, in a region without an organic layer for planarization. The organic layer is typically formed using inkjet printing (IJP) technology.

### SUMMARY

In a first aspect of the present disclosure, the present disclosure provides a display panel. According to embodiments of the present disclosure, the display panel includes: a display region and a bezel region disposed on at least one side of the display region, where the bezel region includes: a substrate; a first insulating layer, where the first insulating layer is disposed on a side of the substrate and extends from the display region to the bezel region; and a plurality of metal traces, where the plurality of metal traces are disposed on a side of the first insulating layer away from the substrate and are arranged sequentially in a direction away from the display region; the plurality of metal traces include a first region and a second region; the first region is disposed between the display region and the second region; an orthographic projection of each of metal traces in the first region on the first insulating layer overlaps with the first insulating layer; the first insulating layer is absent on a side of metal traces in the second region close to the substrate; a distance between a metal trace in the first region closest to the second region and a metal trace in the second region closest to the first region is d1; and a distance between adjacent metal traces in the first region is d2, 10 d2≥d1≥1.5 d2.

According to embodiments of the present disclosure, 20 μm≥d1≥4.1 μm.

According to embodiments of the present disclosure, 20 μm≥d1≥7 μm.

According to embodiments of the present disclosure, each of the plurality of metal traces includes at least one metal layer.

According to embodiments of the present disclosure, the display panel further includes: a second insulating layer, where the second insulating layer is disposed on the side of the first insulating layer away from the substrate; and each of the plurality of metal traces includes a first metal layer and a second metal layer; the second metal layer is disposed on a side of the second insulating layer away from the substrate; the first metal layer is disposed on a side of the second insulating layer close to the substrate; the first metal layer in the first region is disposed between the first insulating layer and the second insulating layer; and an orthographic projection of the second metal layer on the substrate overlaps with an orthographic projection of the first metal layer on the substrate.

According to embodiments of the present disclosure, the orthographic projection of the second metal layer on the substrate substantially coincides with the orthographic projection of the first metal layer on the substrate.

According to embodiments of the present disclosure, at least for the metal trace in the first region closest to the second region and the metal trace in the second region closest to the first region, a first orthographic projection of the second metal layer on the substrate is disposed within a second orthographic projection of the first metal layer on the substrate; and an edge line of the first orthographic projection does not coincide with an edge line of the second orthographic projection.

According to embodiments of the present disclosure, a distance between the edge line of the first orthographic projection and the edge line of the second orthographic projection is greater than or equal to 1.2 μm.

According to embodiments of the present disclosure, a distance d4 between the second metal layer of the metal trace in the first region closest to the second region and the second metal layer of the metal trace in the second region closest to the first region is greater than the distance d1.

According to embodiments of the present disclosure, the plurality of metal traces satisfy a following condition: only for the metal trace in the first region closest to the second region and the metal trace in the second region closest to the first region, the first orthographic projection of the second metal layer on the substrate is disposed within the second orthographic projection of the first metal layer on the substrate; and the edge line of the first orthographic projection does not coincide with the edge line of the second orthographic projection.

According to embodiments of the present disclosure, the plurality of metal traces satisfy a following condition: for each of the plurality of metal traces, the first orthographic projection of the second metal layer on the substrate is within the second orthographic projection of the first metal layer on the substrate, the edge line of the first orthographic projection does not coincide with the edge line of the second orthographic projection, and widths of all second metal layers are the same.

According to embodiments of the present disclosure, the plurality of metal traces satisfy the following condition: for each of the plurality of metal traces, the first orthographic projection of the second metal layer on the substrate is within the second orthographic projection of the first metal layer on the substrate, and the edge line of the first orthographic projection does not coincide with the edge line of the second orthographic projection; widths of second metal layers of the metal traces in the first region gradually decrease in a direction from the display region to the second region; and widths of second metal layers of the metal traces in the second region gradually increase in a direction from the first region to an edge of the display panel.

According to embodiments of the present disclosure, at least for the metal trace in the first region closest to the second region and the metal trace in the second region closest to the first region, an edge line, which is close to the display region, of an orthographic projection of the second metal layer on the substrate is within an orthographic projection of the first metal layer on the substrate; and an edge line, which is away from the display region, of the orthographic projection of the first metal layer on the substrate, is within the orthographic projection of the second metal layer on the substrate.

According to embodiments of the present disclosure, the orthographic projection of the second metal layer of the metal trace in the first region closest to the second region on the substrate does not overlap with the orthographic projection of the first metal layer of the metal trace in the second region closest to the first region on the substrate.

According to embodiments of the present disclosure, the display panel further includes: a second insulating layer, where the second insulating layer is disposed on the side of the first insulating layer away from the substrate; each of the plurality of metal traces includes a first metal layer and a second metal layer; and the first metal layer and the second metal layer are arranged in a same layer and disposed on a side of the second insulating layer close to the first insulating layer.

According to embodiments of the present disclosure, a metal trace farthest from the display region is not electrically connected to any other metal traces.

In another aspect of the present disclosure, the present disclosure provides a display panel, including: a display region and a bezel region disposed on at least one side of the display region, where the bezel region includes: a substrate; a first insulating layer, where the first insulating layer is disposed on a side of the substrate and extends from the display region to the bezel region; and a plurality of metal traces, where the plurality of metal traces are disposed on a side of the first insulating layer away from the substrate and are arranged sequentially in a direction away from the display region; and orthographic projections of the plurality of metal traces on the first insulating layer are within the first insulating layer.

In still another aspect of the present disclosure, the present disclosure provides a preparation method for the above-described display panel, where the display panel includes: a display region and a bezel region disposed on at least one side of the display region; and the preparation method for the display panel includes steps of preparing the bezel region, including: providing a substrate; forming a first insulating layer, where the first insulating layer is formed on a side of the substrate and extends from the display region to the bezel region; and forming a plurality of metal traces, where the plurality of metal traces are disposed on a side of the first insulating layer away from the substrate and are arranged sequentially in a direction away from the display region; the plurality of metal traces include a first region and a second region; the first region is disposed between the display region and the second region; an orthographic projection of each of metal traces in the first region on the first insulating layer overlaps with the first insulating layer; the first insulating layer is absent on a side of metal traces in the second region close to the substrate; a distance between a metal trace in the first region closest to the second region and a metal trace in the second region closest to the first region is d1; and a distance between adjacent metal traces in the first region is d2, 10 d2≥d1≥1.5 d2.

According to embodiments of the present disclosure, the method further includes: forming a second insulating layer, where the second insulating layer is formed on the side of the first insulating layer away from the substrate; and each of the plurality of metal traces includes a first metal layer and a second metal layer; the second metal layer is formed on a side of the second insulating layer away from the substrate; the first metal layer is formed on a side of the second insulating layer close to the substrate; the first metal layer in the first region is disposed between the first insulating layer and the second insulating layer; and an orthographic projection of the second metal layer on the substrate overlaps with an orthographic projection of the first metal layer on the substrate; or, the first metal layer and the second metal layer are arranged in a same layer and disposed on a side of the second insulating layer close to the first insulating layer.

In still yet another aspect of the present disclosure, the present disclosure provides a display apparatus. According to embodiments of the present disclosure, the display apparatus includes a power supply assembly, and the display panel described above, where the power supply assembly is configured to supply power to the display panel.

### BRIEF DESCRIPTION OF DRAWINGS

The foregoing and/or additional aspects and advantages of the present disclosure will become apparent and readily understandable from the description of the embodiments with reference to the following drawings.

FIG. 1 is a structural schematic diagram of a display panel according to an embodiment of the present disclosure;

FIG. 2 is a schematic diagram of a planar structure between a metal trace and a first insulating layer shown in FIG. 1;

FIG. 3 is a structural schematic diagram of a display panel in the prior art;

FIG. 4 is a scanning electron microscope (SEM) image of a partial structure shown in FIG. 3;

FIG. 5 is a structural schematic diagram of a display panel according to another embodiment of the present disclosure;

FIG. 6 is a schematic diagram of a planar structure between a metal trace and a first insulating layer shown in FIG. 5;

FIG. 7 is a structural schematic diagram of a display panel according to still another embodiment of the present disclosure;

FIG. 8 is a structural schematic diagram of a display panel according to still another embodiment of the present disclosure;

FIG. 9 is a structural schematic diagram of a display panel according to still another embodiment of the present disclosure;

FIG. 10 is a structural schematic diagram of a display panel according to still another embodiment of the present disclosure;

FIG. 11 is a structural schematic diagram of a display panel according to still another embodiment of the present disclosure;

FIG. 12 is a structural schematic diagram of a display panel according to still another embodiment of the present disclosure;

FIG. 13 is a schematic diagram of a method flow for preparing a display panel according to still another embodiment of the present disclosure;

FIG. 14 is a schematic diagram of a structural flow for preparing a display panel according to still another embodiment of the present disclosure; and FIG. 15 is a structural schematic diagram of a display apparatus according to still another embodiment of the present disclosure.

### DETAILED DESCRIPTION

The technical solutions of the present disclosure will be described in detail below with reference to specific embodiments. Those skilled in the art should understand that the following embodiments are only intended to illustrate the present disclosure, rather than to limit the scope of the present disclosure. If specific techniques or conditions are not indicated in an example, a process is conducted in accordance with the techniques or conditions described in literatures in the prior art or in accordance with a product specification. All of the used reagents or instruments which are not specified with manufacturers are conventional commercially-available products.

The present disclosure is described below with reference to the specific examples. It should be noted that these examples are only illustrative and do not limit the present disclosure in any way.

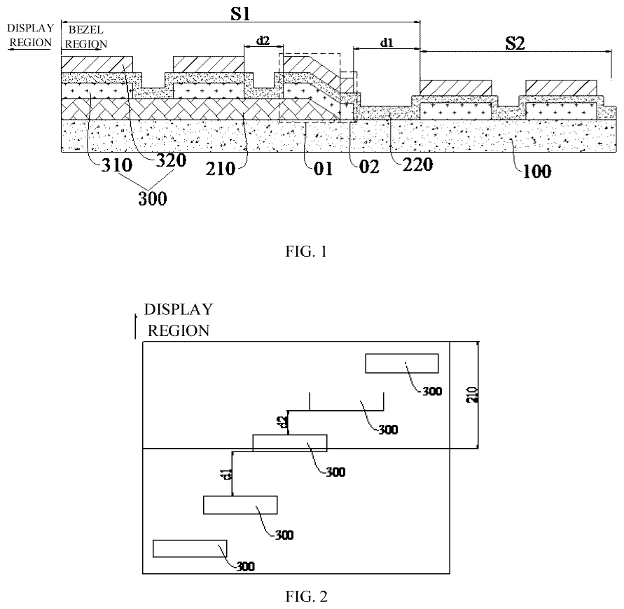

In one aspect of the present disclosure, the present disclosure provides a display panel. According to some embodiments of the present disclosure, referring to FIG. 1 and FIG. 2, the display panel includes a display region and a bezel region disposed on at least one side of the display region. The bezel region includes: a substrate 100, a first insulating layer 210, and a plurality of metal traces 300. The first insulating layer 210 is disposed on a side of the substrate 100, and the first insulating layer 210 extends from the display region to the bezel region. Each of the plurality of metal traces 300 includes at least one metal layer, for example, including a first metal layer 310 and a second metal layer 320. The plurality of metal traces 300 are disposed on a side of the first insulating layer 210 away from the substrate 100 and are arranged sequentially in a direction away from the display region. That is, the plurality of metal traces 300 are arranged sequentially in a direction from the display region towards the bezel region.

As shown in FIG. 1, the metal trace 300 includes a first region S1 and a second region S2. The first region S1 is disposed between the display region and the second region S2. An orthographic projection of the metal trace 300 in the first region S1 on the first insulating layer 210 overlaps with the first insulating layer 210. The first insulating layer 210 is absent on a side of the metal trace 300 in the second region S2 close to the substrate 100 (i.e., directly below the metal trace 300). That is, the metal trace 300 in the second region S2 has no orthographic projection on the first insulating layer 210. In other words, an orthographic projection of the metal trace 300 in the second region S2 on the substrate does not overlap with an orthographic projection of the first insulating layer on the substrate. Furthermore, a distance between a metal trace 300 in the first region S1 closest to the second region S2 and a metal trace 300 in the second region S2 closest to the first region S1 is d1, and a distance between the metal traces in the first region S1 is d2. The distance d1 and the distance d2 satisfy: 10 d2≥d1≥1.5 d2, for example, d1=1.5 d2, d1=2 d2, d1=3 d2, d1=4 d2, d1=5 d2, d1=6 d2, d1=7 d2 , d1=8 d2, d1=9 d2, or d1=10 d2, etc.

In the display panel provided by the embodiments of the present disclosure, the distance between the two adjacent metal traces in the first region and the second region (i.e., the metal trace 300 in the first region S1 closest to the second region S2 and the metal trace 300 in the second region S2 closest to the first region S1) is relatively large. Thus, even if there is some metal filing in the gap between the two metal traces, the two metal traces can still remain non-contact. This design effectively prevents a short circuit between the two adjacent metal traces in the first region and the second region, thereby effectively improving the display quality of the display panel. Moreover, the aforementioned design requirement of 10 d2≥d1≥1.5 d2 can effectively prevent a short circuit between the two adjacent metal traces in the first region and the second region while avoiding a significant impact on the width of the bezel region. Therefore, the narrow bezel design of the display panel can still be achieved. Additionally, since metal filing typically does not occur between adjacent metal traces in the first region and between adjacent metal traces in the second region, there is no need to increase the distance between adjacent metal traces in the first region and the distance between adjacent metal traces in the second region. Therefore, a small distance can still be maintained, facilitating the narrow bezel design for the display panel.

It can be understood that in the embodiments of the present disclosure, in the aforementioned definition of the first region and the second region, the first region includes gaps between the metal traces in the first region, and the gap between the metal trace 300 in the first region S1 closest to the second region S2 and the metal trace 300 in the second region S2 closest to the first region S1 (i.e., the gap corresponding to the distance d1). The second region includes gaps between the metal traces in the second region.

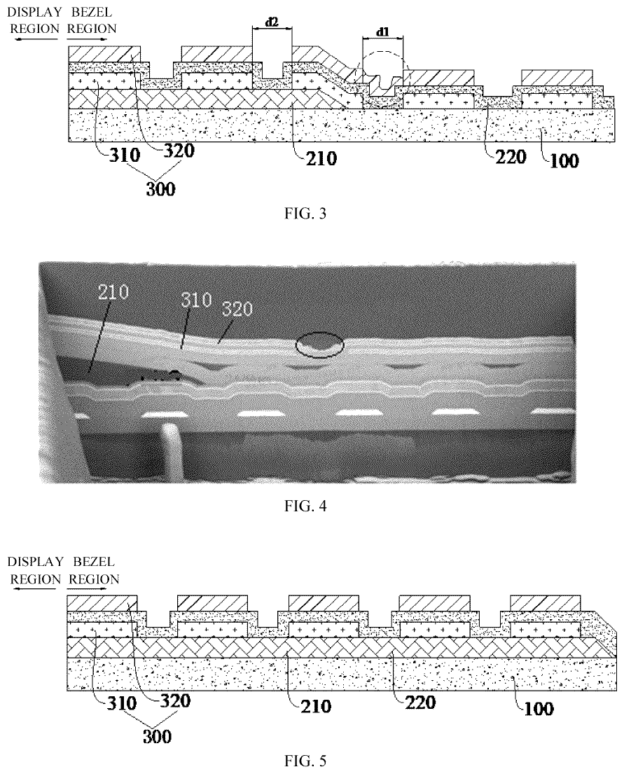

In some embodiments, generally, for all the metal traces of the display panel, the distance between adjacent metal traces is substantially consistent, i.e., d1=d2, and the distance is about 2.5 μm. Referring to FIG. 3 and FIG. 4, for the two adjacent metal traces in the first region and the second region, since the metal trace in the first region is at the end of the first insulating layer, the height variation created by the first insulating layer can easily cause these two adjacent metal traces to be connected, leading to a short circuit. Particularly, in a scheme with the first metal layers and the second metal layers arranged in separate layers, the second metal layers disposed in the upper layer (both the first metal layers and the first insulating layer create height variations) is prone to leave metal filing in the gap between these two adjacent metal traces (indicated by the dashed box in FIG. 3 and the elliptical box in FIG. 4), during the preparation process, for example, during the patterning of the metal layers, due to process reasons and other factors. Consequently, the two adjacent metal traces are connected, thereby resulting in a short circuit. However, the first metal layers in the lower layer typically do not generate or only generate very little metal filing, and do not cause a short circuit. In summary, the short circuit problem caused by metal filing is usually generated by the second metal layer at the height variation of the first insulating layer in the first region. The technical solution provided by the embodiments of the present disclosure can effectively solve the aforementioned technical problem and prevent short circuits.

According to some embodiments of the present disclosure, the specific structure of the substrate is not particularly limited, and those skilled in the art can make flexible selections based on actual situations such as the specific product type of the display panel. In some embodiments, the substrate includes a base substrate, a buffer layer, a thin film transistor, and various signal lines. The buffer layer is disposed on a side of the base substrate. The thin film transistor is disposed on a side of the buffer layer away from the base substrate. Furthermore, the thin film transistor includes a source, a gate, and a drain. The specific structure of the thin film transistor can be a top-gate structure or a bottom-gate structure. The various signal lines can include a data signal line, a gate line, a power line, and a ground line, etc. The data signal line, the gate line, the power line, and the ground line can be arranged in the same layer as structures such as the source or the gate.

According to some embodiments of the present disclosure, referring to FIG. 1, as described above, the orthographic projection of the metal trace 300 in the first region S1 on the first insulating layer 210 overlaps with the first insulating layer 210, which specifically means that: an orthographic projection of a first portion 01 of the metal trace 300 in the first region S1 closest to the second region S2 on the first insulating layer 210 is disposed within the first insulating layer 210, and an orthographic projection of a second portion 02 of the metal trace 300 (a portion close to the second region S2) on the base substrate does not overlap with the first insulating layer 210. The proportion of the first portion 01 and the second portion 02 in the metal trace 300 is not particularly limited, and those skilled in the art can design it flexibly according to actual needs. Except for the metal trace 300 in the first region S1 closest to the second region S2, orthographic projections of other metal traces 300 in the first region on the first insulating layer 210 are all disposed within the first insulating layer 210.

According to some embodiments of the present disclosure, the distance d1 satisfies: 20 μm d1≥4.1 μm. For example, d1 is 4.1 μm, 4.2 μm, 4.5 μm, 4.8 μm, 5.0 μm, 5.2 μm, 5.5 μm, 5.8 μm, 6 μm, 6.3 μm, 6.5 μm, 6.8 μm, 7 μm, 7.2 μm, 7.5 μm, 7.7 μm, 8 μm, 9 μm, 10 μm, 11 μm, 12 μm, 13 μm, 14 μm, 15 μm, 16 μm, 17 μm, 18 μm, 19 μm, or 20 μm, etc.

This distance can well prevent residual metal filing from electrically connecting the metal trace 300 in the first region S1 closest to the second region S2 and the metal trace 300 in the second region S2 closest to the first region S1, thereby avoiding a short circuit. Moreover, the design of the distance can still meet the design requirements of the display panel for a narrow bezel in the bezel region.

Furthermore, in some specific embodiments, the distance d1 satisfies: 20 μm≥d1≥7 μm. The design improves the effect of avoiding a short circuit and achieves a higher product yield.

According to some embodiments of the present disclosure, referring to FIG. 1, the display panel further includes: a second insulating layer 220 which is disposed on the side of the first insulating layer 210 away from the substrate 100. The metal trace 300 includes the first metal layer 310 and the second metal layer 320. The second metal layer 320 is disposed on a side of the second insulating layer 220 away from the substrate 100, and the first metal layer 310 is disposed on a side of the second insulating layer 220 close to the substrate 100. Furthermore, the first metal layer 310 of the first region S1 is disposed between the first insulating layer 210 and the second insulating layer 220. An orthographic projection of the second metal layer 320 on the substrate 100 overlaps with an orthographic projection of the first metal layer 310 on the substrate 100.

By arranging the first metal layer and the second metal layer in separate layers, the present disclosure can effectively ensure the good working performance of the metal trace and effectively avoid a short circuit between the two second metal layers of the two adjacent metal traces in the first region and the second region.

The specific materials of the first insulating layer and the second insulating layer are not particularly limited, and the material of the first insulating layer and the material of the second insulating layer can be the same or different. Those skilled in the art can flexibly select applicable materials in the prior art according to actual situations. In some embodiments, the first insulating layer can be a planarization layer extending from the display region, which can be made of an organic material (such as an insulating organic material like acrylic) or an inorganic material, such as silicon nitride, silicon oxide, or silicon oxynitride. The material of the second insulating layer can be an organic material (such as an insulating organic material like acrylic), or an inorganic material, such as silicon nitride, silicon oxide, or silicon oxynitride.

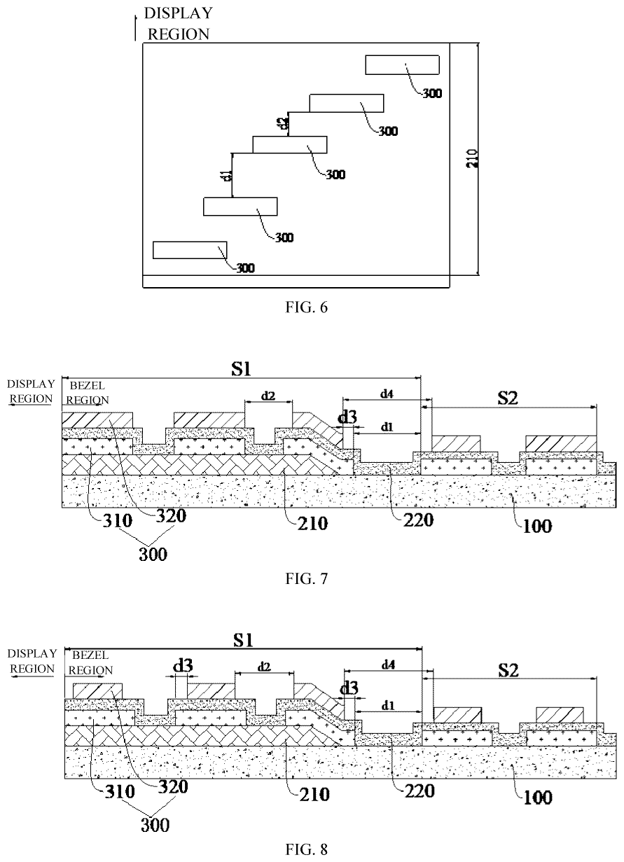

In another aspect of the present disclosure, the present disclosure provides another display panel. According to some embodiments of the present disclosure, referring to FIG. 5 and FIG. 6, the display panel includes a display region and a bezel region disposed on at least one side of the display region. The bezel region includes: a substrate 100, a first insulating layer 210, and a plurality of metal traces 300. The first insulating layer 210 is disposed on a side of the substrate 100, and the first insulating layer 210 extends from the display region to the bezel region. Each of the plurality of metal traces 300 includes at least one metal layer, for example, including a first metal layer 310 and a second metal layer 320. The plurality of metal traces 300 are disposed on a side of the first insulating layer 210 away from the substrate 100 and are arranged sequentially in a direction away from the display region. That is, the plurality of metal traces 300 are arranged sequentially in a direction from the display region towards the bezel region.

Furthermore, in these embodiments, orthographic projections of all metal traces 300 on the first insulating layer 210 are all disposed within the first insulating layer 210. That is, all metal traces are disposed in the first region, and the number of metal traces in the second region is 0. Thus, the first insulating layer is further extended in a direction away from the display region, thereby eliminating the height variation caused by the first insulating layer in the first region. Since there is no height variation, the residual metal filing caused by the height variation can be avoided (i.e., no or less metal filing is generated), further solving the problem of a short circuit occurring in the second metal layer and thereby improving the product yield.

According to some embodiments of the present disclosure, referring to FIG. 1 and FIG. 5, an orthographic projection of the second metal layer 320 on the substrate 100 substantially coincides with an orthographic projection of the first metal layer 310 on the substrate 100. That is, the shapes of the first metal layer and the second metal layer are substantially the same, and their sizes are substantially the same. Thus, the same mask can be used when preparing the first metal layer and the second metal layer, which can increase the preparation speed and reduce preparation costs. In this case, a distance d1 between the metal trace 300 in the first region S1 closest to the second region S2 and the metal trace 300 in the second region S2 closest to the first region S1 refers to a distance between the first metal layer of the metal trace 300 in the first region S1 closest to the second region S2 and the first metal layer of the metal trace 300 in the second region S2 closest to the first region S1. That is, the distance d1 can refer to the distance between the first metal layers of the two adjacent metal traces 300.

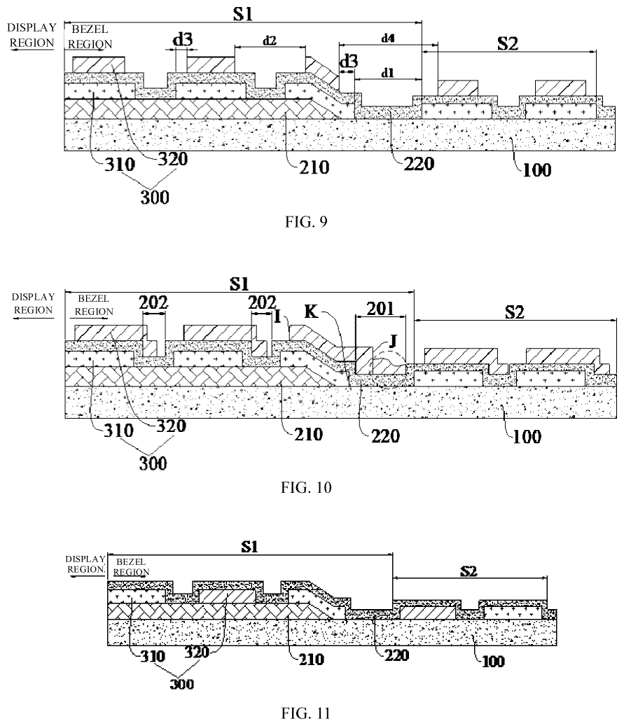

According to some embodiments of the present disclosure, referring to FIG. 7, FIG. 8, and FIG. 9, at least for the metal trace 300 in the first region S1 closest to the second region S2 and the metal trace 300 in the second region S2 closest to the first region S1, a first orthographic projection of the second metal layer 320 on the substrate 100 is disposed within a second orthographic projection of the first metal layer 310 on the substrate, and an edge line of the first orthographic projection does not coincide with an edge line of the second orthographic projection. That is, the second metal layer 320 is indented inward relative to the first metal layer 310 to reduce its size. Therefore, a distance d4 between the second metal layer 320 of the metal trace 300 in the first region S1 closest to the second region S2 and the second metal layer 320 of the metal trace 300 in the second region S2 closest to the first region S1 is increased. Furthermore, this can further avoid a short circuit caused by metal filing and improve the product yield. Moreover, compared to the structure shown in FIG. 1, this design does not affect the bezel width, that is, it still helps the display panel meet the design requirements for a narrow bezel.

It can be understood that in FIG. 7, only the second metal layer 320 of the metal trace 300 in the first region S1 closest to the second region S2 and the second metal layer 320 of the metal trace 300 in the second region S2 closest to the first region S1 are indented inward. In FIG. 8, the second metal layers 320 of all the metal traces 300 are indented inward. That is, the sizes of the second metal layers 320 of all the metal traces 300 are consistent to reduce the difficulty of the preparation process.

Optionally, in some embodiments of the present disclosure, referring to FIG. 7, FIG. 8, and FIG. 9, a distance d3 between an edge line of the first orthographic projection of the second metal layer 320 on the substrate and an edge line of the second orthographic projection of the first metal layer 310 on the substrate (i.e., the unilateral indented size of the second metal layer 320 in the first region) is greater than or equal to 1.2 μm.

Thus, there is sufficient space in the process to design the aforementioned indented structure of the second metal layer, which facilitates the implementation of the preparation process while not affecting the working effect of the second metal layer. Furthermore, according to the above description, in this structure, due to the indented configuration of the second metal layer 320, the distance between the second metal layer 320 of the metal trace 300 in the first region S1 closest to the second region S2 and the second metal layer 320 of the metal trace 300 in the second region S2 closest to the first region S1 satisfies: d4>d1, and d4>d2. The relationship between d1 and d2 is determined based on d3.

Optionally, in some embodiments of the present disclosure, referring to FIG. 7, only for the metal trace 300 in the first region S1 closest to the second region S2 and the metal trace 300 in the second region S2 closest to the first region S1, the first orthographic projection of the second metal layer 320 on the substrate 100 is disposed within the second orthographic projection of the first metal layer 310 on the substrate 100, and the edge line of the first orthographic projection does not coincide with the edge line of the second orthographic projection. In other words, only the width of the second metal layer 320 of the metal trace 300 in the first region S1 closest to the second region S2 and the width of the second metal layer 320 of the metal trace 300 in the second region S2 closest to the first region S1 are reduced, such that they are indented relative to the first metal layer 310, that is, the width of the second metal layer 320 of the metal trace 300 in the first region S1 closest to the second region S2 is less than the width of the second metal layers 320 of other metal traces 300 in the first region S1, and is also less than the width of each of the second metal layers 320 of the metal traces 300 in the second region S2.

Thus, the distance d4 between the second metal layer 320 of the metal trace 300 in the first region S1 closest to the second region S2 and the second metal layer 320 of the metal trace 300 in the second region S2 closest to the first region S1 is further increased, which further avoids a short circuit caused by metal filing and improves the product yield. Moreover, compared to the structure shown in FIG. 1, this design does not affect the bezel width, that is, it still helps the display panel meet the design requirements for a narrow bezel. In these embodiments, for the remaining metal traces 300, the orthographic projection of the second metal layer 320 on the substrate 100 may coincide with the orthographic projection of the first metal layer 310 on the substrate 100.

Optionally, in some embodiments of the present disclosure, referring to FIG. 8, widths of all second metal layers 320 in the bezel region are reduced, and the widths of all second metal layers 320 are the same. Thus, on the basis of further avoiding a short circuit caused by metal filing and improving the product yield, since the size of the second metal layers is consistent, the difficulty of the preparation process can be reduced. Moreover, compared to the structure shown in FIG. 1, this design does not affect the bezel width, that is, it still helps the display panel meet the design requirements for a narrow bezel.

Optionally, in some embodiments of the present disclosure, referring to FIG. 9, for all the metal traces 300, the first orthographic projection of the second metal layer 320 on the substrate 100 is disposed within the second orthographic projection of the first metal layer 310 on the substrate 100, and the edge line of the first orthographic projection does not coincide with the edge line of the second orthographic projection. However, the width of the second metal layer 320 in the metal trace 300 of the first region S1 gradually decreases in a direction from the display region to the second region S2, that is, the unilateral indented size d3 of the second metal layer in the first region gradually increases. For example, the width of the second metal layer 320 of the metal trace 300 in the first region S1 closest to the second region S2 is one-half of the width of the first metal layer 310 of the corresponding metal trace 300. The width of the second metal layer 320 in the metal trace 300 of the second region S2 gradually increases in a direction from the first region S1 to an edge of the display panel. For example, the width of the second metal layer 320 of the metal trace 300 in the second region S2 closest to the first region S1 is one-half of the width of the first metal layer 310 of the corresponding metal trace 300.

Thus, there is sufficient space in the process to design the aforementioned indented structure of the second metal layer, which facilitates the implementation of the preparation process while not affecting the working effect of the second metal layer. The manner of setting the width of the second metal layer can further avoids a short circuit caused by metal filing and improve the product yield. Moreover, compared to the structure shown in FIG. 1, this design does not affect the bezel width, that is, it still helps the display panel meet the design requirements for a narrow bezel.

According to some embodiments of the present disclosure, referring to FIG. 10, to better solve the aforementioned short circuit problem, at least the second metal layer 320 of the metal trace 300 in the first region S1 closest to the second region S2 and the second metal layer 320 of the metal trace 300 in the second region S2 closest to the first region S1 can be offset relative to the first metal layer 310. Specifically, in some embodiments, an edge line I of the orthographic projection of the second metal layer 320 on the substrate 100, which is close to the display region, is disposed within the orthographic projection of the first metal layer 310 on the substrate 100, and an edge line K of the orthographic projection of the first metal layer 310 on the substrate 100, which is away from the display region, is disposed within the orthographic projection of the second metal layer 320 on the substrate 100. That is, the second metal layer 320 is moved a certain distance relative to the first metal layer 310 in a direction away from the display region, such that an edge line J of the second metal layer 320 of the metal trace 300 in the first region S1 closest to the second region S2 falls within a first groove 201 of the second insulating layer 220 and the edge line J is away from the display region. The first groove 201 refers to a groove created by the second insulating layer 220 between the metal trace 300 in the first region S1 closest to the second region S2 and the metal trace 300 in the second region S2 closest to the first region S1. In other words, as shown in FIG. 10, the first groove 201 refers to a groove created by the metal trace 300 in the first region S1 closest to the second region and the second insulating layer 220.

Thus, even if the second metal layer 320 of the metal trace 300 in the first region S1 closest to the second region S2 generates metal filing (indicated by the dashed circle shown in FIG. 10), due to the presence of the first groove 201 and the aforementioned offset configuration of the second metal layer 320 of the metal trace 300 in the second region S2 closest to the first region S1, the metal filing cannot cross the first groove 201. This design prevents the metal filing from contacting the second metal layer 320 of the metal trace 300 in the second region S2 closest to the first region S1, thereby avoiding a short circuit.

Optionally, as shown in FIG. 10, a width of the first groove 201 in the first region S1 is greater than a width of a second groove 202. The second groove 202 refers to a groove created by another metal trace 300 in the first region S1 and the second insulating layer 220. As mentioned above, this configuration can better avoid a short circuit.

Optionally, as shown in FIG. 10, the orthographic projection of the second metal layer 320 of the metal trace 300 in the first region closest to the second region on the substrate 100 does not overlap with the orthographic projection of the first metal layer 310 of the metal trace in the second region closest to the first region on the substrate 100. As mentioned above, this configuration can better avoid a short circuit.

According to some embodiments of the present disclosure, the first metal layers 310 and the second metal layers 320 are arranged in a double-layer configuration. As mentioned earlier, the first metal layers 310 disposed below do not cause metal filing or only cause very little metal filing. According to some embodiments of the present disclosure, referring to FIG. 11, the first metal layers 310 and the second metal layers 320 are arranged in the same layer and are disposed on a side of the second insulating layer 220 close to the first insulating layer 210. That is, the second metal layers 320 are arranged in the same layer as the first metal layers 310. This design can also avoid a short circuit between adjacent metal layers. The distance between the first metal layer 310 and the second metal layer 320 can be adjusted flexibly, as long as no short circuit occurs. Meanwhile, the d2 width design can also be retained between the metal layers to facilitate the narrow bezel design.

According to some embodiments of the present disclosure, referring to FIG. 1, and FIG. 5 to FIG. 12, the second region S2 may include one or two metal traces 300. Therefore, the first insulating layer 210 may have a suitable length in the bezel region, which facilitates improving the performance of the display panel. In some embodiments, the second region S2 includes two metal traces 300, i.e., including two metal traces 300 farthest from the display region. In some other embodiments, the second region S2 includes only one metal trace 300, i.e., only including a metal trace 300 farthest from the display region.

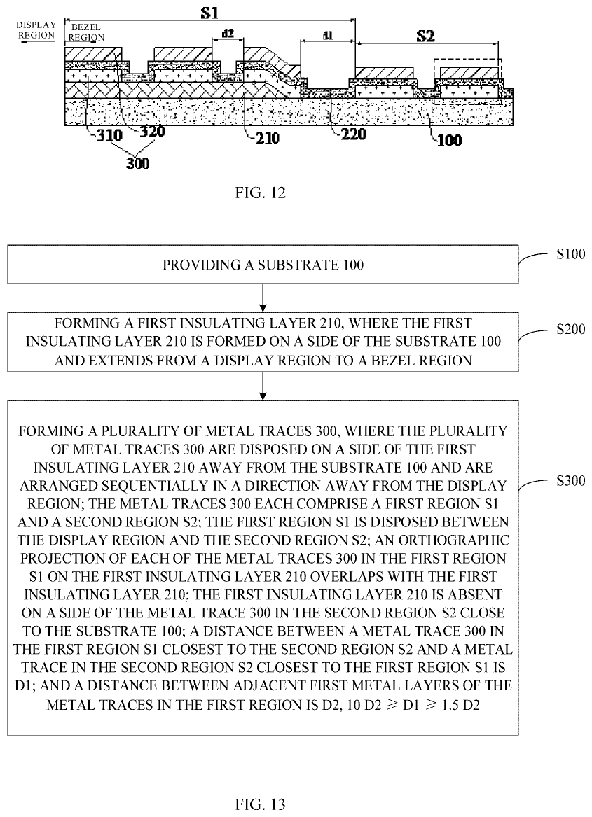

According to some embodiments of the present disclosure, referring to FIG. 1, and FIG. 5 to FIG. 12, the metal trace 300 farthest from the display region (i.e., the metal trace 300 at an outermost edge of the bezel region, namely, the metal trace in the dashed box shown in FIG. 12) is not electrically connected to any other metal traces. Thus, the metal trace 300 farthest from the display region (i.e., the metal trace 300 at the outermost edge of the bezel region) may serve as a shielding protection metal line to prevent the external environment from interfering with the electrical signals of other metal traces.

According to some embodiments of the present disclosure, the display panel can be applied to a touch display apparatus, which further includes a touch panel. The aforementioned metal traces 300 can be arranged in the same layer as touch electrodes in the touch panel, for example, the metal traces 300 can be arranged in the same layer as touch electrodes TX or touch electrodes RX in the touch panel.

According to some embodiments of the present disclosure, the bezel region of the present disclosure is disposed on at least one side of the display region, and a plurality of touch electrodes TX or touch electrodes RX are distributed in a first direction of the display region. For example, the bezel region is disposed below the display region, and a plurality of touch electrodes TX (i.e., TX0, TX1, TX2, TX3, . . . , TX14, TX15, etc.) are distributed in the first direction of the display region. The specific positions of the plurality of touch electrodes TX corresponding to the gap between the metal trace 300 in the first region S1 closest to the second region S2 and the metal trace 300 in the second region S2 closest to the first region S1 are not particularly limited, and those skilled in the art can flexibly choose the positions according to the actual situation. In some embodiments, the gap between the metal trace 300 in the first region S1 closest to the second region S2 and the metal trace in the second region S2 closest to the first region S1 corresponds to the touch electrode TX12.

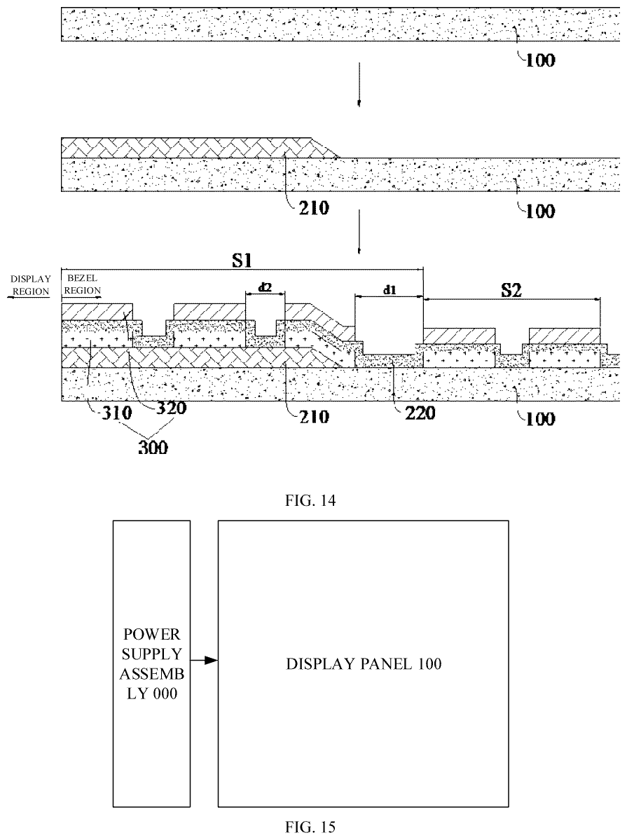

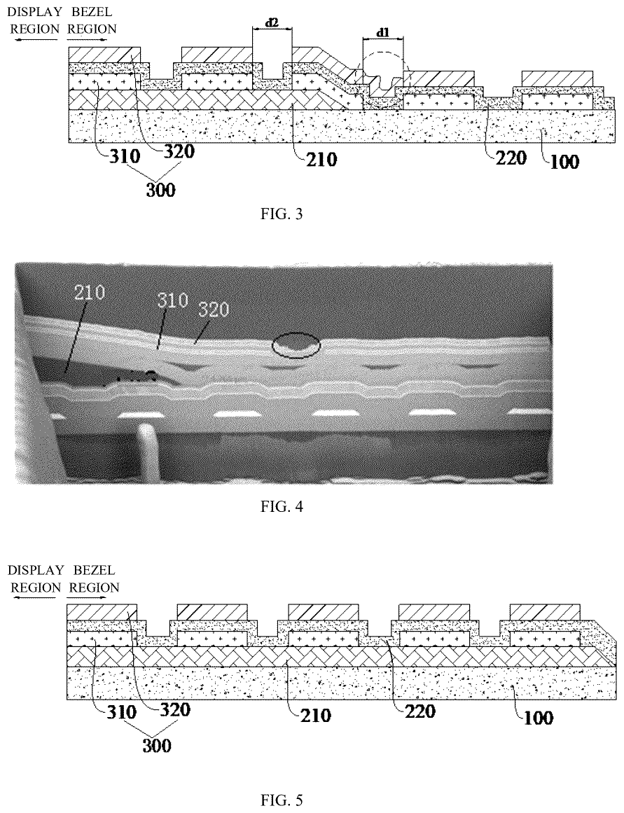

In another aspect of the present disclosure, the present disclosure provides a preparation method for the aforementioned display panel. The display panel includes the display region and the bezel region disposed on at least one side of the display region. Referring to FIG. 13 and FIG. 14, the preparation method for the display panel includes steps for preparing the bezel region. The steps for preparing the bezel region are as follows.

In step S100, a substrate 100 is provided.

In step S200, a first insulating layer 210 is formed. The first insulating layer 210 is disposed on a side of the substrate 100 and extends from the display region to the bezel region.

In step S300, a plurality of metal traces 300 are formed. The plurality of metal traces 300 are disposed on a side of the first insulating layer 210 away from the substrate 100 and are arranged sequentially in a direction away from the display region. Each of the plurality of metal traces 300 is divided into a first region S1 and a second region S2. The first region S1 is disposed between the display region and the second region S2. An orthographic projection of the metal trace 300 in the first region S1 on the first insulating layer 210 overlaps with the first insulating layer 210. The first insulating layer 210 is absent on a side of the metal trace 300 in the second region S2 close to the substrate 100. A distance between the metal trace 300 in the first region S1 closest to the second region S2 and the metal trace in the second region S2 closest to the first region S1 is d1, and the distance between adjacent the metal traces in the first region is d2, where 10 d2≥d1≥1.5 d2.

According to some embodiments of the present disclosure, in the aforementioned preparation process, the distance between adjacent metal traces in the first region and the second region is increased. Even if there is some metal filing in the gap between the two metal traces, they can still remain non-contact. In this way, it can effectively prevent a short circuit between the two adjacent metal traces in the first region and the second region, thereby improving preparation yield and productivity.

Optionally, each of the plurality of metal traces 300 includes at least one metal layer.

According to some embodiments of the present disclosure, referring to FIG. 14 and FIG. 11, the preparation method for the display panel further includes: a second insulating layer 220 is formed. The second insulating layer 220 is formed on a side of the first insulating layer 210 away from the substrate 100. The metal trace 300 includes a first metal layer 310 and a second metal layer 320. There are two manner of setting the first metal layer 310 and the second metal layer 320: a double-layer configuration and a same-layer configuration. Specifically:

Referring to FIG. 14, the second metal layer 320 is formed on a side of the second insulating layer 220 away from the substrate 100, and the first metal layer 310 is formed on a side of the second insulating layer 220 close to the substrate 100. The first metal layer 310 of the first region S1 is disposed between the first insulating layer 210 and the second insulating layer 220. An orthographic projection of the second metal layer 320 on the substrate 100 overlaps with an orthographic projection of the first metal layer 310 on the substrate 100. The specific configuration requirements for the first metal layer 310 and the second metal layer 320 can be referred to FIG. 1, FIG. 4 to FIG. 10, and the above description, and will not be repeated here.

Referring to FIG. 11, the first metal layer 310 and the second metal layer 320 are arranged in the same layer and are disposed on a side of the second insulating layer 220 close to the first insulating layer 210. That is, the second metal layer is disposed in the same layer as the first metal layer. In this way, it can avoid a short circuit between adjacent metal layers. The distance between the first metal layer and the second metal layer can be adjusted flexibly, as long as no short circuit occurs. Meanwhile, the d2 width design can also be retained between the metal layers to facilitate the narrow bezel design.

In yet another aspect of the present disclosure, the present disclosure provides a display apparatus. According to some embodiments of the present disclosure, the display apparatus includes the aforementioned display panel 100. Therefore, the display apparatus has high reliability and excellent display quality. Those skilled in the art can understand that the display apparatus has all the features and advantages of the aforementioned display panel, which will not be elaborated here. As shown in FIG. 15, the display apparatus further includes a power supply assembly 000 which is configured to supply power to the display panel 100.

According to some embodiments of the present disclosure, the specific type of the display apparatus is not particularly limited, and those skilled in the art can make flexible choices according to actual situations. For example, the display apparatus can be a mobile phone, a computer, an iPad, a kindle, a game console, or any display apparatus with a display function.

Those skilled in the art can understand that the display apparatus, in addition to the aforementioned display panel, includes structures or components essential for a conventional display apparatus. Taking a mobile phone as an example, in addition to the aforementioned display panel, it also includes essential structures or components such as a cover plate, a touch panel, a fingerprint module, an audio module, a camera module, a central processing unit (CPU), a battery, a rear cover, and a middle frame.

The terms such as “first” and “second” herein are used only for descriptive purposes, and should not be construed as indicating or implying relative importance or implying the number of indicated technical features. Thus, features defined with “first” and “second” may explicitly or implicitly include one or more of the features. In the description of the present application, “multiple” means two or more, unless otherwise specifically defined.

In the description of this specification, the description with reference to the terms such as “one embodiment”, “some embodiments”, “an example”, “a specific example”, or “some examples”, etc. means that the specific features, structures, materials, or characteristics described with reference to the embodiment or example are included in at least one embodiment or example of the present disclosure. In this specification, the schematic expression of the above terms is not necessarily directed to the same embodiment or example. Moreover, the specific features, structures, materials, or characteristics described may be combined in a suitable manner in any one or more embodiments or examples. In addition, those skilled in the art may combine different embodiments or examples described in this specification and characteristics of the different embodiments or examples without mutual contradiction.

Although the embodiments of the present disclosure have been illustrated and described, it may be understood that the foregoing embodiments are examples instead of limitations to the present disclosure. A person of ordinary skill in the art can make various changes, modifications, replacements, and variations on the foregoing embodiments within the scope of the present disclosure.

1. A display panel, comprising: a display region and a bezel region disposed on at least one side of the display region, wherein the bezel region comprises:
a substrate;
a first insulating layer, wherein the first insulating layer is disposed on a side of the substrate and extends from the display region to the bezel region; and
a plurality of metal traces, wherein the plurality of metal traces are disposed on a side of the first insulating layer away from the substrate and are arranged sequentially in a direction away from the display region; the plurality of metal traces comprise a first region and a second region; the first region is disposed between the display region and the second region; an orthographic projection of each of metal traces in the first region on the first insulating layer overlaps with the first insulating layer; the first insulating layer is absent on a side of metal traces in the second region close to the substrate; a distance between a metal trace in the first region closest to the second region and a metal trace in the second region closest to the first region is d1; and a distance between adjacent metal traces in the first region is d2, wherein, 10 d2≥d1≥1.5 d2.

2. The display panel according to claim 1, wherein 20 μm>d1≥4.1 μm.

3. The display panel according to claim 2, wherein 20 μm>d1≥7 μm.

4. The display panel according to claim 1, wherein each of the plurality of metal traces comprises at least one metal layer.

5. The display panel according to claim 4, further comprising a second insulating layer, wherein the second insulating layer is disposed on the side of the first insulating layer away from the substrate; and
each of the plurality of metal traces comprises a first metal layer and a second metal layer; the second metal layer is disposed on a side of the second insulating layer away from the substrate; the first metal layer is disposed on a side of the second insulating layer close to the substrate; the first metal layer in the first region is disposed between the first insulating layer and the second insulating layer; and an orthographic projection of the second metal layer on the substrate overlaps with an orthographic projection of the first metal layer on the substrate.

6. The display panel according to claim 5, wherein the orthographic projection of the second metal layer on the substrate substantially coincides with the orthographic projection of the first metal layer on the substrate.

7. The display panel according to claim 5, wherein at least for the metal trace in the first region closest to the second region and the metal trace in the second region closest to the first region, a first orthographic projection of the second metal layer on the substrate is disposed within a second orthographic projection of the first metal layer on the substrate; and an edge line of the first orthographic projection does not coincide with an edge line of the second orthographic projection.

8. The display panel according to claim 7, wherein a distance between the edge line of the first orthographic projection and the edge line of the second orthographic projection is greater than or equal to 1.2 μm.

9. The display panel according to claim 7, wherein a distance d4 between the second metal layer of the metal trace in the first region closest to the second region and the second metal layer of the metal trace in the second region closest to the first region is greater than the distance d1.

10. The display panel according to claim 7, wherein the plurality of metal traces satisfy a following condition:
only for the metal trace in the first region closest to the second region and the metal trace in the second region closest to the first region, the first orthographic projection of the second metal layer on the substrate is within the second orthographic projection of the first metal layer on the substrate; and the edge line of the first orthographic projection does not coincide with the edge line of the second orthographic projection.

11. The display panel according to claim 7, wherein the plurality of metal traces satisfy a following condition:
for each of the plurality of metal traces, the first orthographic projection of the second metal layer on the substrate is within the second orthographic projection of the first metal layer on the substrate, the edge line of the first orthographic projection does not coincide with the edge line of the second orthographic projection, and widths of all second metal layers are the same.

12. The display panel according to claim 7, wherein the plurality of metal traces satisfy a following condition:
for each of the plurality of metal traces, the first orthographic projection of the second metal layer on the substrate is within the second orthographic projection of the first metal layer on the substrate, and the edge line of the first orthographic projection does not coincide with the edge line of the second orthographic projection; widths of second metal layers of the metal traces in the first region gradually decrease in a direction from the display region to the second region; and widths of second metal layers of the metal traces in the second region gradually increase in a direction from the first region to an edge of the display panel.

13. The display panel according to claim 4, wherein at least for the metal trace in the first region closest to the second region and the metal trace in the second region closest to the first region, an edge line, which is close to the display region, of an orthographic projection of the second metal layer on the substrate is within an orthographic projection of the first metal layer on the substrate; and an edge line, which is away from the display region, of the orthographic projection of the first metal layer on the substrate is within the orthographic projection of the second metal layer on the substrate.

14. The display panel according to claim 10, wherein the orthographic projection of the second metal layer of the metal trace in the first region closest to the second region on the substrate does not overlap with the orthographic projection of the first metal layer of the metal trace in the second region closest to the first region on the substrate.

15. The display panel according to claim 4, further comprising a second insulating layer, wherein the second insulating layer is disposed on the side of the first insulating layer away from the substrate; each of the plurality of metal traces comprises a first metal layer and a second metal layer; and the first metal layer and the second metal layer are arranged in a same layer and disposed on a side of the second insulating layer close to the first insulating layer.

16. The display panel according to claim 1, wherein a metal trace farthest from the display region is not electrically connected to any other metal traces.

17. A display panel, comprising: a display region and a bezel region disposed on at least one side of the display region, wherein the bezel region comprises:
a substrate;
a first insulating layer, wherein the first insulating layer is disposed on a side of the substrate and extends from the display region to the bezel region; and
a plurality of metal traces, wherein the plurality of metal traces are disposed on a side of the first insulating layer away from the substrate and are arranged sequentially in a direction away from the display region; and orthographic projections of the plurality of metal traces on the first insulating layer are within the first insulating layer.

18. A preparation method for a display panel, wherein the display panel comprises: a display region and a bezel region disposed on at least one side of the display region; and the preparation method for the display panel comprises steps of preparing the bezel region, comprising:
providing a substrate;
forming a first insulating layer, wherein the first insulating layer is formed on a side of the substrate and extends from the display region to the bezel region; and
forming a plurality of metal traces, wherein the plurality of metal traces are disposed on a side of the first insulating layer away from the substrate and are arranged sequentially in a direction away from the display region; the plurality of metal traces comprise a first region and a second region; the first region is disposed between the display region and the second region; an orthographic projection of each of metal traces in the first region on the first insulating layer overlaps with the first insulating layer; the first insulating layer is absent on a side of metal traces in the second region close to the substrate; a distance between a metal trace in the first region closest to the second region and a metal trace in the second region closest to the first region is d1; and a distance between adjacent metal traces in the first region is d2, wherein, 10 d2≥d1≥1.5 d2.

19. The method according to claim 18, further comprising: forming a second insulating layer, wherein the second insulating layer is formed on the side of the first insulating layer away from the substrate; and each of the plurality of metal traces comprises a first metal layer and a second metal layer;
the second metal layer is formed on a side of the second insulating layer away from the substrate; the first metal layer is formed on a side of the second insulating layer close to the substrate; the first metal layer in the first region is disposed between the first insulating layer and the second insulating layer; and an orthographic projection of the second metal layer on the substrate overlaps with an orthographic projection of the first metal layer on the substrate; or,
the first metal layer and the second metal layer are arranged in a same layer and disposed on a side of the second insulating layer close to the first insulating layer.

20. A display apparatus, comprising a power supply assembly, and the display panel according to claim 1, wherein the power supply assembly is configured to supply power to the display panel.
